(19) United States
(12) Patent Application Publication
(10) Pub. No.: US 2026/0223563 A1
(43) Pub. Date: Jul. 30, 2026

(54) STRETCHABLE DISPLAY DEVICE

(71) Applicant: Sharp Display Technology Corporation, Kameyama City, Mie (JP)

(72) Inventors: Tetsuya HANAMOTO, Kameyama City, Mie (JP); Noriko WATANABE, Kameyama City, Mie (JP)

(21) Appl. No.: 19/147,446

(22) PCT Filed: Jan. 13, 2023
(86) PCT No.: PCT/JP2023/000706

§ 371 Date: Jul. 11, 2025

(51) Int. Cl. H10K 59/35; H10K 102/00

(52) U.S. Cl. CPC H10K 59/353; H10K 2102/311

(57) ABSTRACT

A stretchable display device includes an upper substrate stretchable in a first direction parallel to a surface, a lower substrate positioned below the upper substrate and being less stretchable in the first direction than the upper substrate, adjacent pixels provided on the upper substrate, and pixels provided on the lower substrate.

### TECHNICAL FIELD

The disclosure relates to a stretchable display device having stretchability.

### BACKGROUND ART

As a stretchable display device having stretchability, a stretchable display device is known that includes an upper substrate stretchable in a first direction parallel to a surface, a lower substrate positioned below the upper substrate and stretchable in the first direction, upper pixels provided on the upper substrate, and lower pixels provided on the lower substrate (PTL 1).

### CITATION LIST

### Patent Literature

PTL 1: US 2019/0043454 A

### SUMMARY OF INVENTION

### Technical Problem

In a conventional stretchable display device having stretchability, there is a problem that, when the stretchable display device is subject to a force and is pulled, this results in a shift in wavelength, a decrease in a total amount of light, and a deterioration in resolution. This is because gaps are generated between the pixels as a result of being pulled. Therefore, there is demand for a stretchable display device in which a total amount of light is not reduced, and which is also capable of preventing a deterioration in resolution.

### Solution to Problem

A stretchable display device according to an aspect of the disclosure includes an upper substrate stretchable in a first direction parallel to a surface, a lower substrate positioned below the upper substrate and being less stretchable in the first direction than the upper substrate, a first pixel and a second pixel provided on the upper substrate, and being adjacent to each other, and a third pixel provided on the lower substrate.

### Advantageous Effects of Invention

According to an aspect of the disclosure, it is possible to provide a stretchable display device in which a total amount of light is not reduced, and which is also capable of preventing a deterioration in resolution.

### BRIEF DESCRIPTION OF DRAWINGS

FIG. 1 is a cross-sectional view of a stretchable display device according to a first embodiment.

FIG. 2 is a cross-sectional view of main portions of the stretchable display device.

FIG. 3 is a plan view of the stretchable display device.

FIG. 4 is a cross-sectional view illustrating an operation of the stretchable display device.

FIG. 5 is a plan view illustrating the operation of the stretchable display device.

FIG. 6 is a cross-sectional view of main components of a modified example of the stretchable display device.

FIG. 7 is a cross-sectional view illustrating an operation of the modified example of the stretchable display device.

FIG. 8 is a view illustrating a light guide layer provided in the modified example of the stretchable display device.

FIG. 9 is a view illustrating another example of the light guide layer provided in the modified example of the stretchable display device.

FIG. 10 is a view illustrating yet another example of the light guide layer provided in the modified example of the stretchable display device.

FIG. 11 is a plan view illustrating a modified example of pixels provided in the stretchable display device.

FIG. 12 is a plan view illustrating a modified example of pixels provided in the stretchable display device.

FIG. 13 is a plan view illustrating a modified example of pixels provided in the stretchable display device.

FIG. 14 is a plan view illustrating a modified example of pixels provided in the stretchable display device.

FIG. 15 is cross-sectional view illustrating another operation of the stretchable display device.

FIG. 16 is a cross-sectional view of another modified example of the stretchable display device.

FIG. 17 is a cross-sectional view illustrating an operation of the other modified example of the stretchable display device.

FIG. 18 is a cross-sectional view of the stretchable display device according to a modified example of the first embodiment.

FIG. 19 is a cross-sectional view illustrating an operation of the stretchable display device.

FIG. 20 is a cross-sectional view illustrating another operation of the stretchable display device.

FIG. 21 is a cross-sectional view illustrating yet another operation of the stretchable display device.

FIG. 22 is a cross-sectional view of a stretchable display device according to a second embodiment.

FIG. 23 is a cross-sectional view of main portions of the stretchable display device.

FIG. 24 is a plan view of the stretchable display device.

FIG. 25 is a cross-sectional view illustrating an operation of the stretchable display device.

FIG. 26 is a plan view illustrating the operation of the stretchable display device.

FIG. 27 is a plan view illustrating a modified example of pixels provided at the stretchable display device.

FIG. 28 is a cross-sectional view illustrating another operation of the stretchable display device.

FIG. 29 is a plan view illustrating an example of stretching of the stretchable display device.

FIG. 30 is a plan view illustrating another example of the stretching of the stretchable display device.

FIG. 31 is a plan view illustrating yet another example of the stretching of the stretchable display device.

FIG. 32 is a cross-sectional view illustrating a manufacturing method of the stretchable display device according to a third embodiment.

### DESCRIPTION OF EMBODIMENTS

### First Embodiment

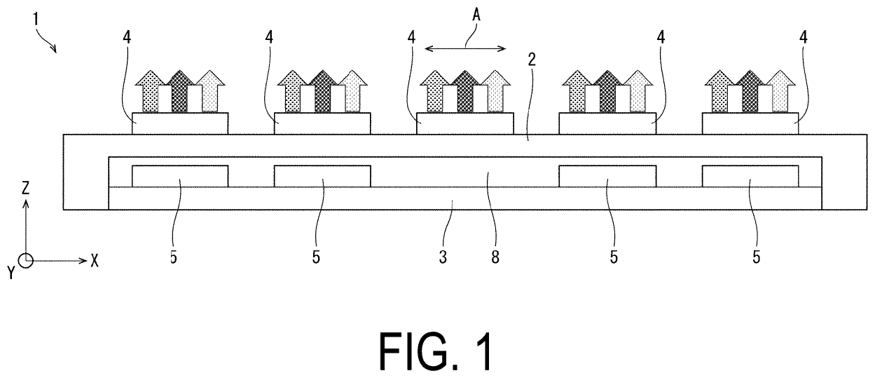

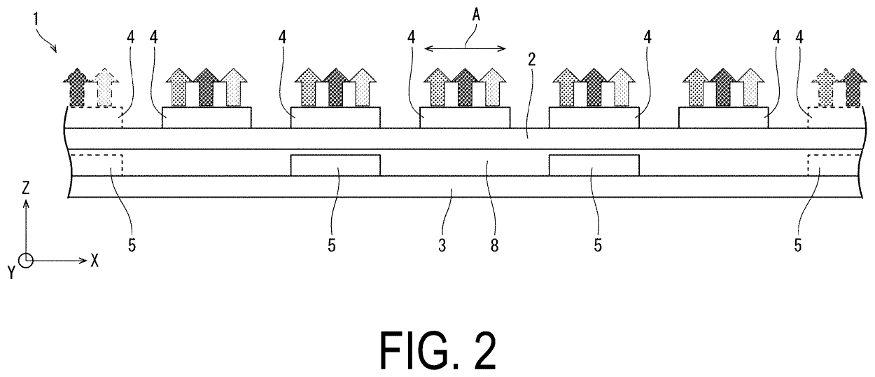

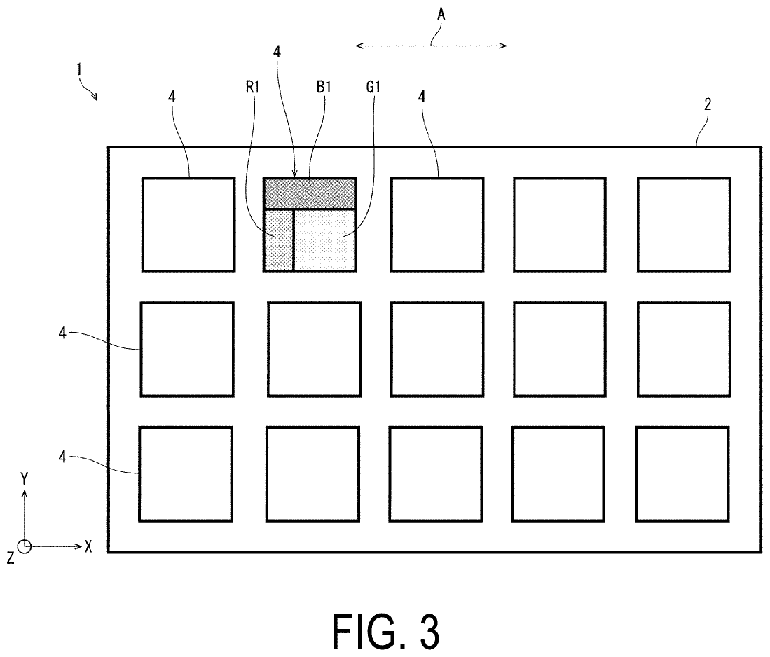

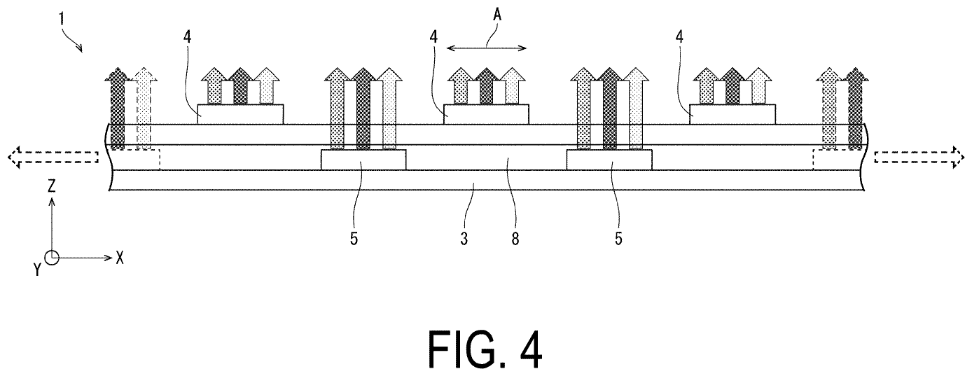

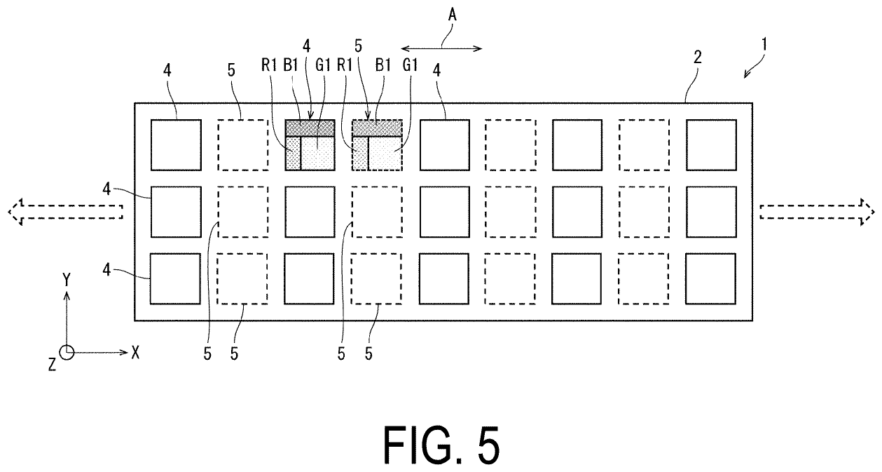

FIG. 1 is a cross-sectional view of a stretchable display device 1 according to a first embodiment. FIG. 2 is a cross-sectional view of main portions of the stretchable display device 1. FIG. 3 is a plan view of the stretchable display device 1. FIG. 4 is a cross-sectional view illustrating an operation of the stretchable display device 1. FIG. 5 is a plan view illustrating the operation of the stretchable display device 1.

The stretchable display device 1 includes an upper substrate 2 that is stretchable in a direction (first direction) indicated by an arrow A parallel to a surface thereof, a lower substrate 3 that is positioned below the upper substrate 2 and that is less stretchable in the direction indicated by the arrow A than the upper substrate 2, a plurality of pixels 4 (first pixels, second pixels) provided in a matrix on the upper substrate 2, and a plurality of pixels 5 (third pixels) provided in a matrix on the lower substrate 3. The upper substrate 2 preferably contains an elastic polymer. The Young's modulus of the upper substrate 2 is preferably equal to or less than 10 MPa.

It is sufficient that the direction indicated by the arrow A in which the upper substrate 2 stretches is a direction parallel to the surface of the upper substrate 2. For example, in addition to an X direction and a Y direction, an oblique direction between the X direction and the Y direction is also included.

In a state (first state) illustrated in FIGS. 1 to 3 in which the upper substrate 2 is not stretched, the pixels 4 and the pixels 5 overlap each other in a plan view. In other words, the pixel 5 is disposed at a substantially central position below the pixel 4. Note that the pixel 5 may be disposed so as to partially overlap the pixel 4. Further, an area of the pixel 5 may be larger than an area of the pixel 4.

In a state (second state) illustrated in FIGS. 4 and 5 in which the upper substrate 2 is stretched in the direction indicated by the arrow A, a gap between the pixels 4 adjacent to each other along the direction indicated by the arrow A overlaps the pixel 5 in a plan view. The pixels 5 of the lower substrate 3 can be turned on or off, and the light emission intensity thereof can be adjusted in accordance with the width of the gap between the pixels 4 at given locations of the upper substrate 2. Even when the upper substrate 2 is stretched in the direction indicated by the arrow A, the pixel 4 itself is not extended. Since the lower substrate 3 is less stretchable than the upper substrate 2, when the upper substrate 2 is stretched in the direction indicated by the arrow A, the gap between the pixels 4 adjacent to each other along the direction indicated by the arrow A in a plan view is widened, and the pixel 5 appears in the gap.

The upper substrate 2 covers side surfaces of the lower substrate 3.

A thixotropic material 8 is filled between the lower substrate 3 and the upper substrate 2. The thixotropic material 8 covers the pixels 5. The thixotropic material is preferably in a liquid state (sol state) or a semi-solid state (gel state). The Young's modulus of the thixotropic material is preferably equal to or less than the Young's modulus of the upper substrate 2. The Young's modulus of the thixotropic material is preferably equal to or less than one half of the Young's modulus of the lower substrate 3. A void may be formed around the pixel 5 that is not filled with the thixotropic material 8.

Each of the pixels 4 and 5 includes subpixels R1, C1, and B1 that emit light of different colors. As illustrated in FIGS. 3 and 5, the subpixels R1, G1, and B1 have different light-emitting areas. A light-emitting area ratio between the subpixels R1, G1, and B1 is the same for the pixel 4 and for the pixel 5. Therefore, when the upper substrate 2 is pulled, the pixel 5 having the same light-emitting area ratio as the light-emitting area ratio of the pixel 4 of the upper substrate 2 appears in the gap between the pixels 4.

The light-emitting area ratio between the light-emitting area of the subpixel R1, the light-emitting area of the subpixel G1, and the light-emitting area of the subpixel B1 of the pixel 4 is the same as the light-emitting area ratio between the light-emitting area of the subpixel R1, the light-emitting area of the subpixel 11, and the light-emitting area of the subpixel B1 of the pixel

A periphery of the stretchable display device 1. Is held by a material having stretchability.

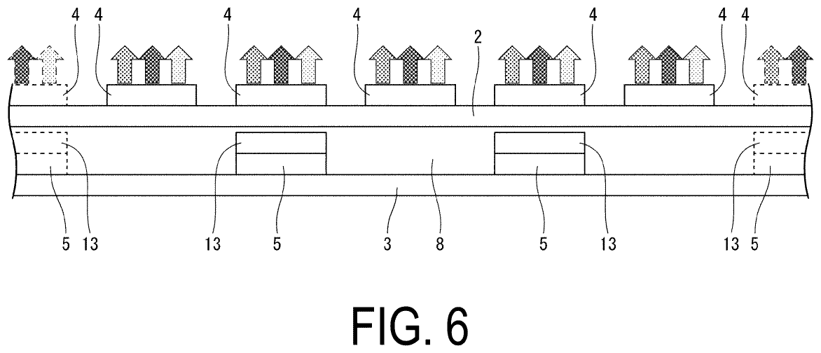

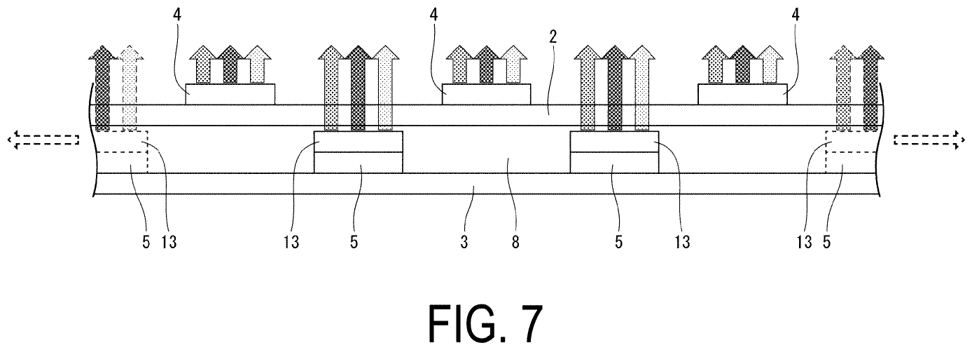

FIG. 6 is a cross-sectional view of main components of a modified example of the stretchable display device. FIG. 7 is a cross-sectional view illustrating an operation of the modified example of the stretchable display device. Constituent elements similar to/same as the constituent elements described above are given the same reference numerals. Thus, detailed descriptions of the constituent elements are not repeated.

The stretchable display device 1 may include a light guide layer 13 overlapping the pixel 5 in a plan view. The light guide layer 13 is disposed on the pixel 5 and is provided to guide the light emitted from the pixel 5 so that the light is emitted perpendicularly in the direction of the upper substrate 2. As a result, the light emitted from the pixel 5 passes between the pixels 4 without being diffused in a lateral direction.

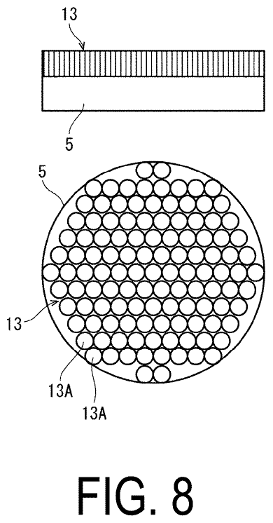

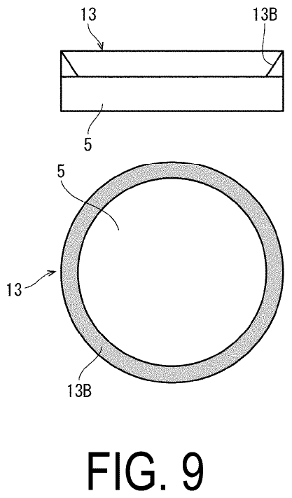

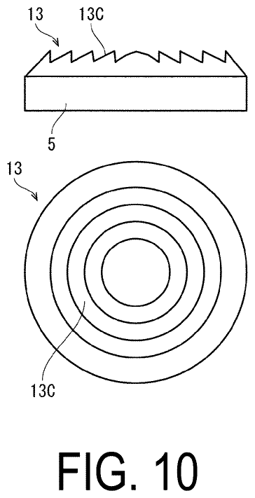

FIG. 8 is a view illustrating the light guide layer 13. FIG. 9 is a view illustrating another example of the light guide layer 13. FIG. 10 is a view illustrating yet another example of the light guide layer 13. Constituent elements similar to/same as the constituent elements described above are given the same reference numerals. Thus, detailed descriptions of the constituent elements are not repeated.

As illustrated in FIG. 8, the light guide layer 13 may include a plurality of light guides 13A. The light guide 13A may be constituted by optical fibers, for example.

As illustrated in FIG. 9, the light guide layer 13 may include a reflective partition 13B formed along the outer peripheral edge of the pixel 5.

As illustrated in FIG. 10, the light guide layer 13 may include a Fresnel lens 13C.

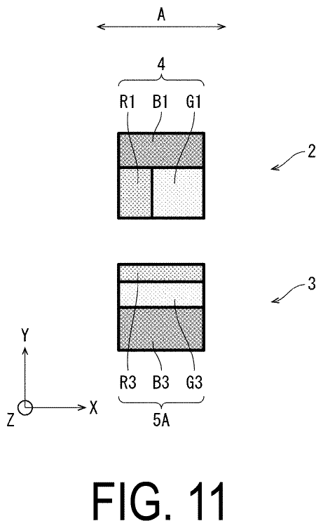

FIGS. 11 to 14 are plan views illustrating modified examples of the pixels 4 and 5 provided in the stretchable display device 1 Constituent elements similar to/same as the constituent elements described above are given the same reference numerals. Thus, detailed descriptions of the constituent elements are not repeated.

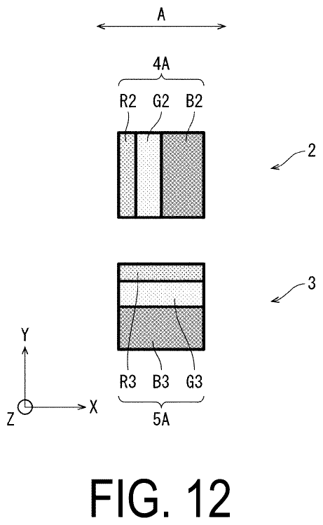

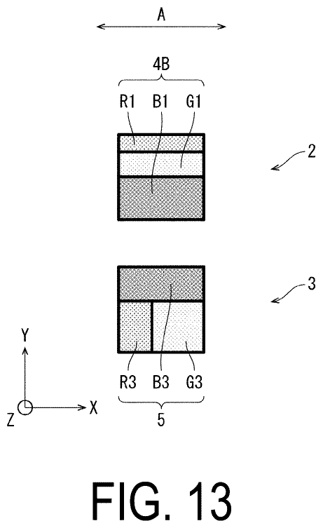

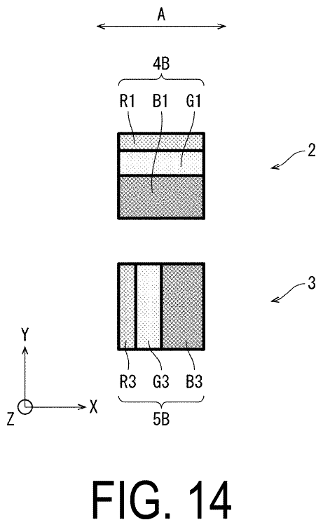

As illustrated in FIG. 12, in a pixel 4A, subpixels R2, G2, and B2 having different areas and emitting light of different colors may be arranged in this order along the X direction. As illustrated in FIGS. 13 and 14, in a pixel 4B, the subpixels R1, G1, and B1 having the different areas and emitting light of different colors may be arranged in this order along the Y direction.

As illustrated in FIG. 11, in a pixel 5A, subpixels R3, G3, and B3 having different areas and emitting light of different colors may be arranged in this order along the Y direction. In addition, as illustrated in FIG. 14, in a pixel 5B, the subpixels R3, G3, and B3 having different areas and emitting light of different colors may be arranged along the X direction.

The stretchable display device 1 may include the pixel 4 on the upper substrate 2, and the pixel 5A on the lower substrate 3, as illustrated in FIG. 11, or may include the pixel 4A on the upper substrate 2 and the pixel 5A on the lower substrate 3, as illustrated in FIG. 12. Further, the stretchable display device 1 may include the pixel 4B on the upper substrate 2 and the pixel 5 on the lower substrate 3, as illustrated in FIG. 13, or may include the pixel 4B on the upper substrate 2 and the pixel 5B on the lower substrate 3, as illustrated in FIG. 14.

The light-emitting area ratio between the light-emitting area of the subpixel R1, the light-emitting area of the subpixel G1, and the light-emitting area of the subpixel B1 of the pixel 4 illustrated in FIG. 1I is the same as the light-emitting area ratio between the light-emitting area of the subpixel R3, the light-emitting area of the subpixel G3, and the light-emitting area of the subpixel B3 of the pixel 5A.

The light-emitting area ratio between the light-emitting area of the subpixel R2, the light-emitting area of the subpixel G2, and the light-emitting area of the subpixel B2 of the pixel 4A illustrated in FIG. 12 is the same as the light-emitting area ratio between the light-emitting area of the subpixel R3, the light-emitting area of the subpixel G3, and the light-emitting area of the subpixel B3 of the pixel 5A.

The light-emitting area ratio between the light-emitting area of the subpixel R1, the light-emitting area of the subpixel G1, and the light-emitting area of the subpixel B1 of the pixel 4B illustrated in FIG. 13 is the same as the light-emitting area ratio between the light-emitting area of the subpixel R3, the light-emitting area of the subpixel G3, and the light-emitting area of the subpixel B3 of the pixel 5.

The light-emitting area ratio between the light-emitting area of the subpixel R1, the light-emitting area of the subpixel G1, and the light-emitting area of the subpixel B1 of the pixel 4B illustrated in FIG. 14 is the same as the light-emitting area ratio between the light-emitting area of the subpixel R3, the light-emitting area of the subpixel G3, and the light-emitting area of the subpixel B3 of the pixel 5B.

By adopting such a configuration, when the upper substrate 2 is stretched in the direction indicated by the arrow A, the pixels 5, 5A, and 5B on the lower substrate 3 that appear between the pixels 4, 4A and 4B appear at substantially the same area ratio as the pixels of the upper substrate 2. Thus, even when the pixels on the lower substrate 3 do not completely appear, variations in the color tone of the pixels can be reduced. As long as the light emission intensity of the subpixels of the lower substrate 3 can be the same, the subpixels that emit light of different colors may have the same light-emitting area.

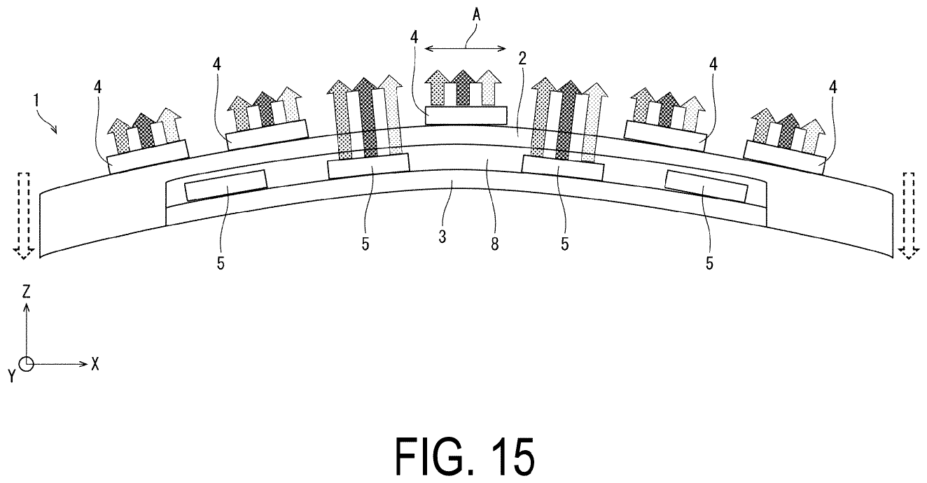

FIG. 15 is a cross-sectional view illustrating another operation of the stretchable display device 1. Constituent elements similar to/same as the constituent elements described above are given the same reference numerals. Thus, detailed descriptions of the constituent elements are not repeated.

As illustrated in FIG. 15, when the upper substrate 2 is stretched along the direction indicated by the arrow A, the upper substrate 2 may be curved in an upwardly convex shape. Even when the upper substrate 2 is stretched in the upwardly convex shape, the pixel 4 itself is not extended.

The lighting control of the pixel 5 is performed in accordance with the size of the gap between the pixels 4 adjacent to each other. For example, since the gap between the second pixel 4 from the left and the third pixel 4 from the left illustrated in FIG. 15 is sufficiently large in relation to the pixel 5, the pixel 5 present between both the pixels 4 in a plan view is controlled to be turned on. On the other hand, since the gap between the first pixel 4 from the left and the second pixel 4 from the left is not sufficiently large in relation to the pixel 5, the pixel 5 present between both the pixels 4 in a plan view is controlled to be turned off.

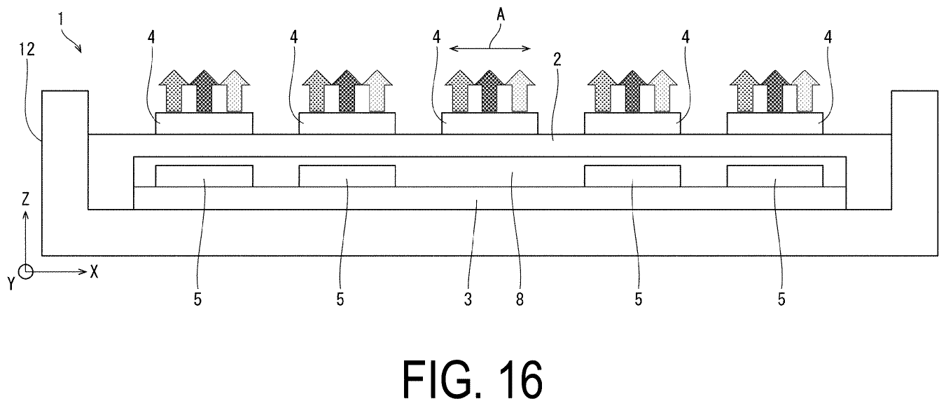

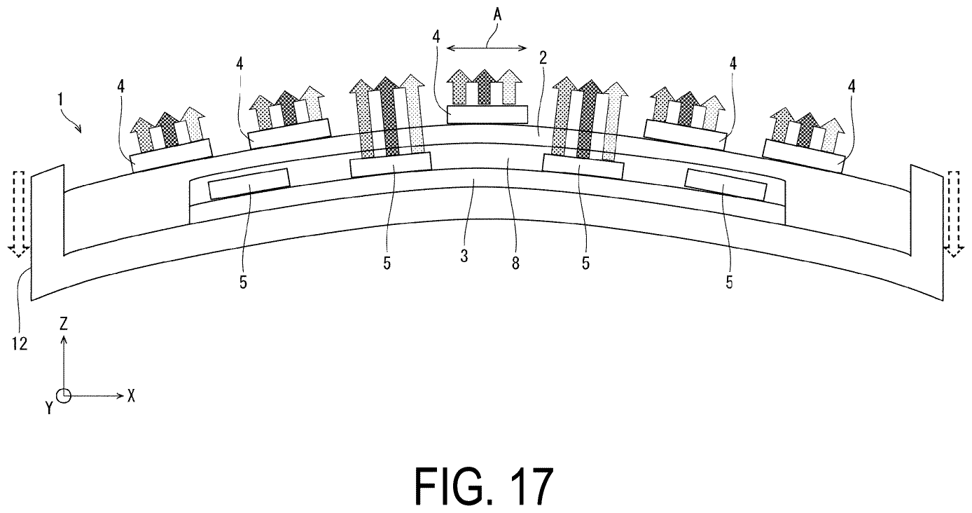

FIG. 16 is a cross-sectional view of another modified example of the stretchable display device 1. FIG. 17 is a cross-sectional view illustrating an operation of the other modified example of the stretchable display device 1. Constituent elements similar to/same as the constituent elements described above are given the same reference numerals, Thus, detailed descriptions of the constituent elements are not repeated.

The stretchable display device 1 may include a housing 12 that holds the upper substrate 2. Both ends of the tipper substrate 2 covering the side surfaces of the lower substrate 3 are fixed to the housing 12. The side surfaces of the lower substrate 3 are fixed to both the ends of the upper substrate 2. A gap is formed between the lower substrate 3 and the housing 12, and the lower substrate 3 is not fixed to the housing 12.

As illustrated in FIG. 17, when the housing 12 is curved in an upwardly convex shape, the upper housing 2, both ends of which are fixed to the housing 12, is stretched so as to be curved in the upwardly convex shape. The lower substrate 3, which is less stretchable than the upper housing 2, stretches less than the upper housing 2.

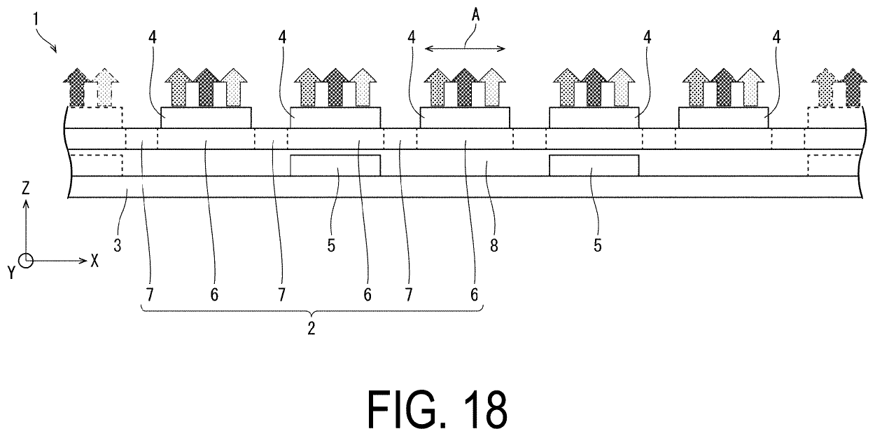

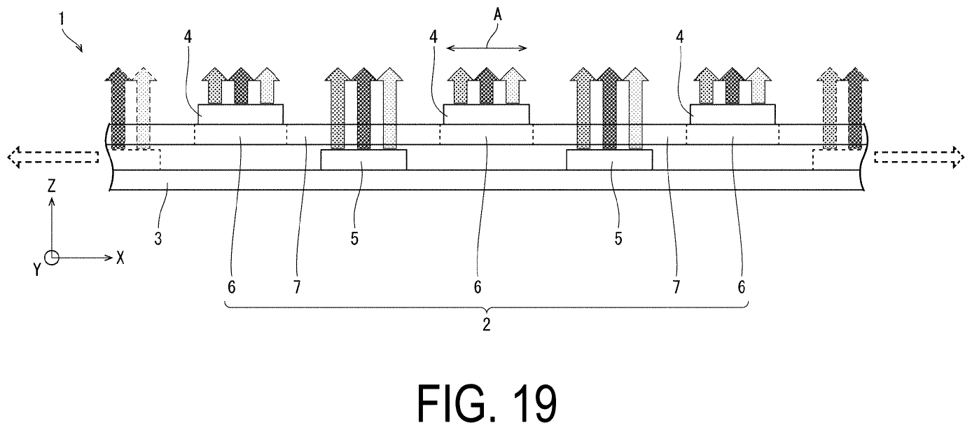

FIG. 18 is a cross-sectional view of the stretchable display device 1 according to a modified example of the first embodiment. FIG. 19 is a cross-sectional view illustrating an operation of the stretchable display device 1. Constituent elements similar to/same as the constituent elements described above are given the same reference numerals. Thus, detailed descriptions of the constituent elements are not repeated.

The upper substrate 2 includes upper stretching regions 7 and upper holding regions 6 that are less stretchable than the upper stretching regions 7. The upper stretching regions 7 and the upper holding regions 6 are alternately arranged along the direction indicated by the arrow A The pixel 4 is provided on the upper holding region 6.

Thus, when the upper substrate 2 stretches in the direction of the arrow A, the upper stretching region 7 of the upper substrate 2 stretches in the direction of the arrow A, and the upper holding region 6 stretches less than the upper stretching region 7. Therefore, the pixel 4 provided on the upper holding region 6 is protected from the stretching of the tipper substrate 2.

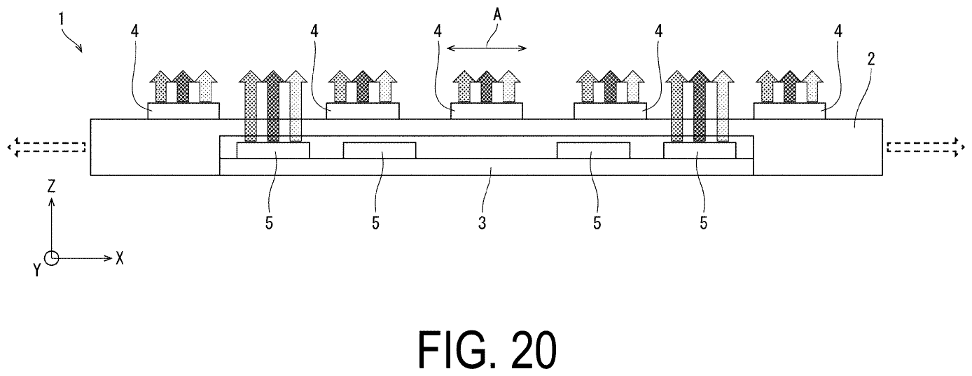

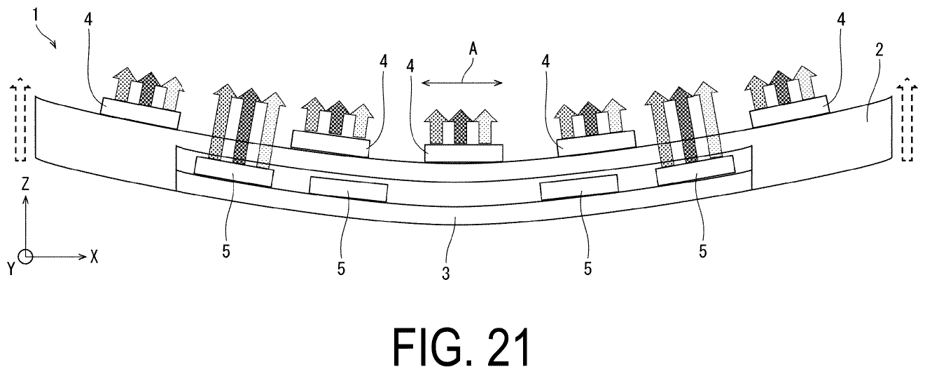

FIG. 20 is a cross-sectional view illustrating another operation of the stretchable display device 1. FIG. 21 is a cross-sectional view illustrating yet another operation of the stretchable display device 1. Constituent elements similar to/same as the constituent elements described above are given the same reference numerals. Thus, detailed descriptions of the constituent elements are not repeated.

The pixels 5 provided on the lower substrate 3 can be turned on or off, and the light emission intensity or the like thereof can be adjusted in accordance with the width of the gap between the adjacent pixels 4 provided on the upper substrate 2. For example, the pixel 5 on the leftmost side is subjected to lighting control and is adjusted so as to increase the light emission intensity thereof, since the gap between the pixels 4 adjacent to each other corresponding to that pixel 5 is widened as a result of the upper substrate 2 being pulled in the direction of the arrow A. On the other hand, the second pixel 5 from the left is controlled to be turned off, or the light emission intensity thereof is adjusted to be weak, since the gap between the adjacent pixels 4 corresponding to that pixel 5 is not widened as a result of the upper substrate 2 being pulled in the direction of the arrow A, and that pixel 5 is positioned below the pixel 4.

As illustrated in FIG. 21, when the upper substrate 2 is stretched, the upper substrate 2 may be curved in a downwardly convex shape. Also in this case, as illustrated in FIG. 21, the pixels 5 provided on the lower substrate 3 can be turned on or off, and the light emission intensity or the like thereof can be adjusted in accordance with the width of the gap between the adjacent pixels 4 provided on the upper substrate 2.

In this way, the stretchable display device 1 has a two layer structure of the pixels 4 of the upper substrate 2 and the pixels 5 of the lower substrate 3, and the upper substrate 2 is freely stretchable. Then, when the upper substrate 2 is stretched, the pixels 5 of the lower substrate 3 are caused to be exposed at gap sections between the pixels 4 of the upper substrate 2 and are caused to emit light. Accordingly, it is possible to provide the stretchable display device 1 in which a total amount of light is not reduced, and which is also capable of preventing a deterioration in resolution.

Further, by filling the thixotropic material 8 having thixotropic properties between the lower substrate 3 and the upper substrate 2, it is also possible to reduce a shift in wavelengths due to a change in the film thickness of the pixel 5 of the lower substrate 3.

### Second Embodiment

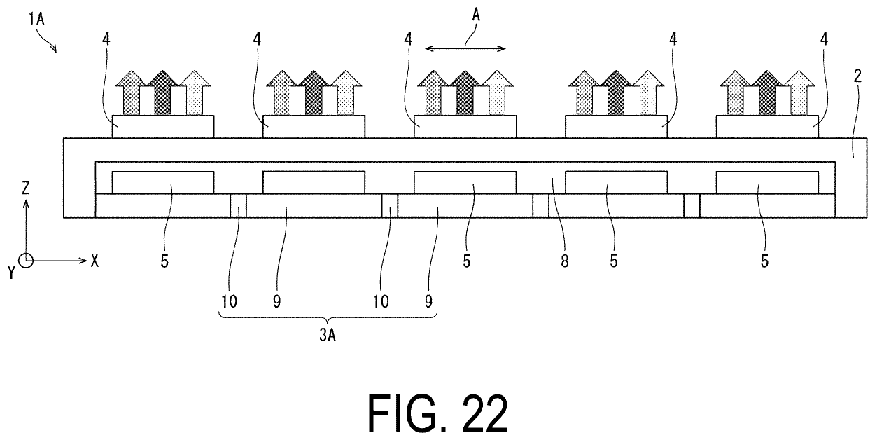

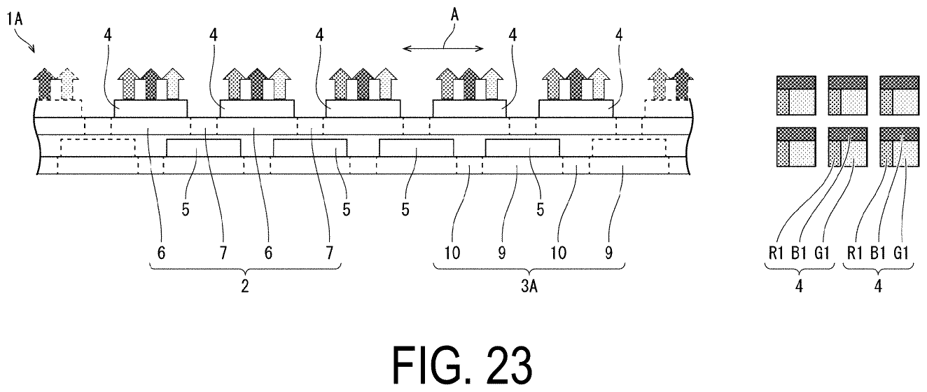

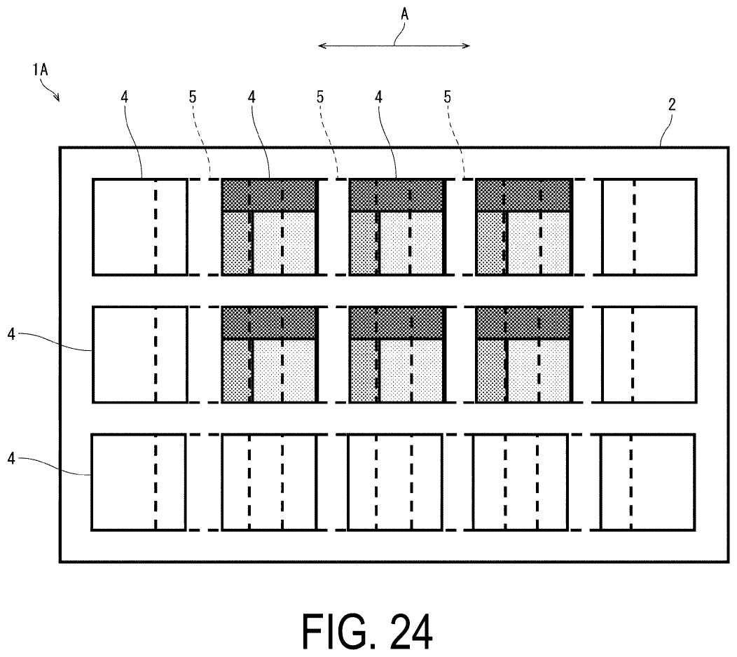

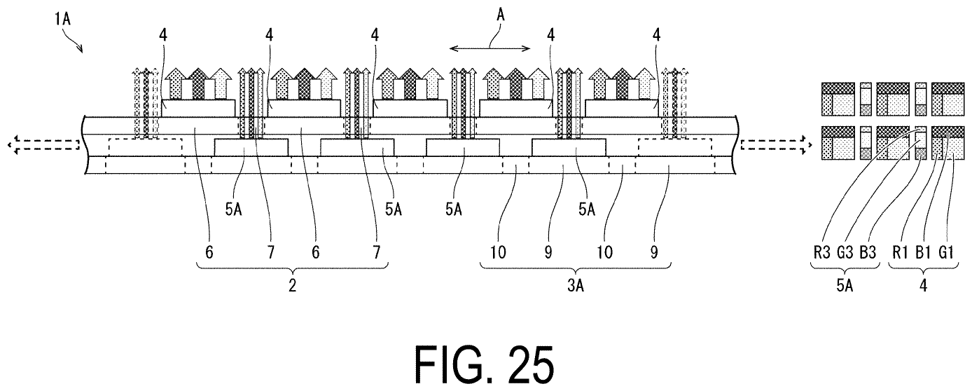

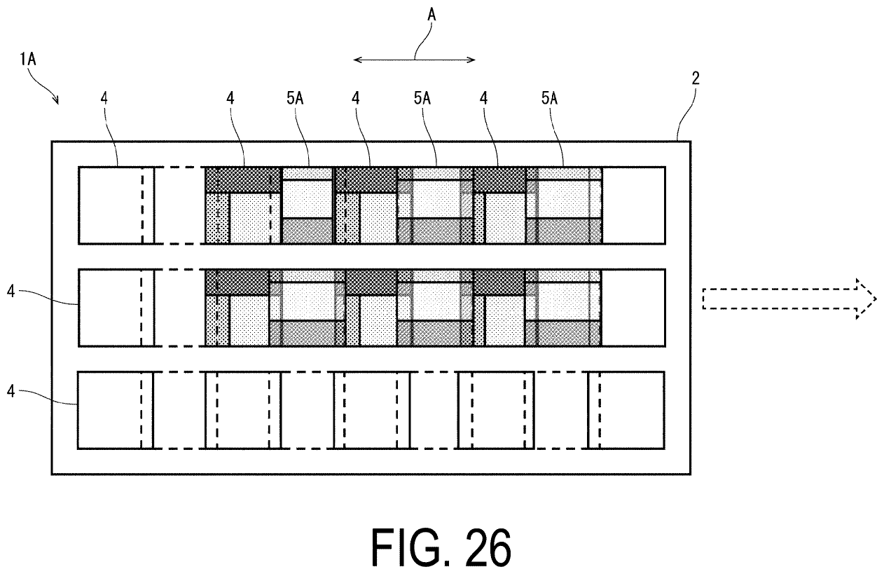

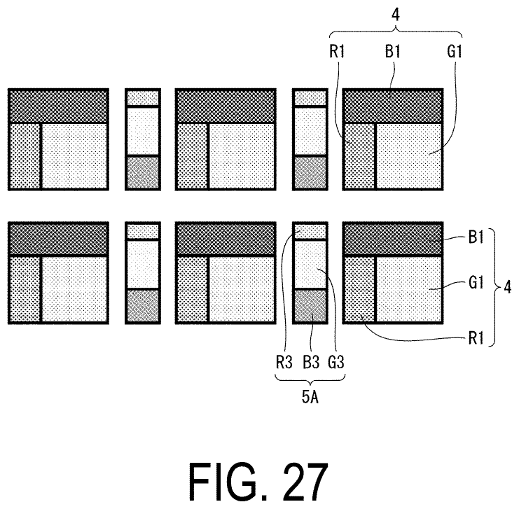

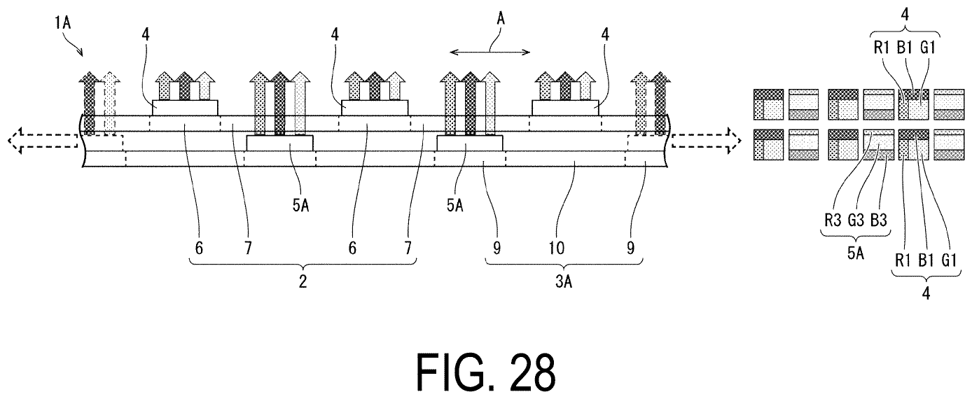

FIG. 22 is a cross-sectional view of a stretchable display device 1A according to a second embodiment. FIG. 23 is a cross-sectional view of main portions of the stretchable display device 1A. FIG. 24 is a plan view of the stretchable display device 1A. FIG. 25 is a cross-sectional view illustrating an operation of the stretchable display device 1A. FIG. 26 is a plan view illustrating the operation of the stretchable display device 1A. FIG. 27 is a plan view illustrating a modified example of the pixels 4 and 5 provided at the stretchable display device 1A. FIG. 28 is a cross-sectional view illustrating another operation of the stretchable display device 1A. Constituent elements similar to/same as the constituent elements described above are given the same reference numerals. Thus, detailed descriptions of the constituent elements are not repeated.

The stretchable display device 1A includes a lower substrate 3A. The lower substrate 3A includes lower holding regions 9 and lower stretching regions 10 that are more stretchable than the lower holding regions 9. The lower holding regions 9 and the lower stretching regions 10 are alternately arranged along the direction indicated by the arrow A. The third pixel 5A is provided on the lower holding region 9. The lower stretching region 10 is positioned below the gap between the pixels 4 adjacent to each other.

It is preferable that the stretchability of the lower substrate 3A in the direction illustrated by the arrow A is uniform as a whole.

As illustrated in FIGS. 25 and 28, the pixel 3A provided on the lower substrate 5A can be turned on or off, and the light emission intensity or the like thereof can be adjusted in accordance with the width of the gap between the adjacent pixels 4 provided on the upper substrate 2. For example, for the pixels 5A illustrated in FIG. 25, since the gaps between the adjacent pixels 4 corresponding to the pixels 5A are not sufficiently widened as a result of the upper substrate 2 being pulled in the direction of the arrow A, the lighting control is performed to weaken the light emission intensity.

Then, for the pixels 5A illustrated in FIG. 28, since the gaps between the adjacent pixels 4 corresponding to the pixels 5A are sufficiently widened as a result of the upper substrate 2 being further pulled in the direction of the arrow A, the lighting control is performed to increase the light emission intensity.

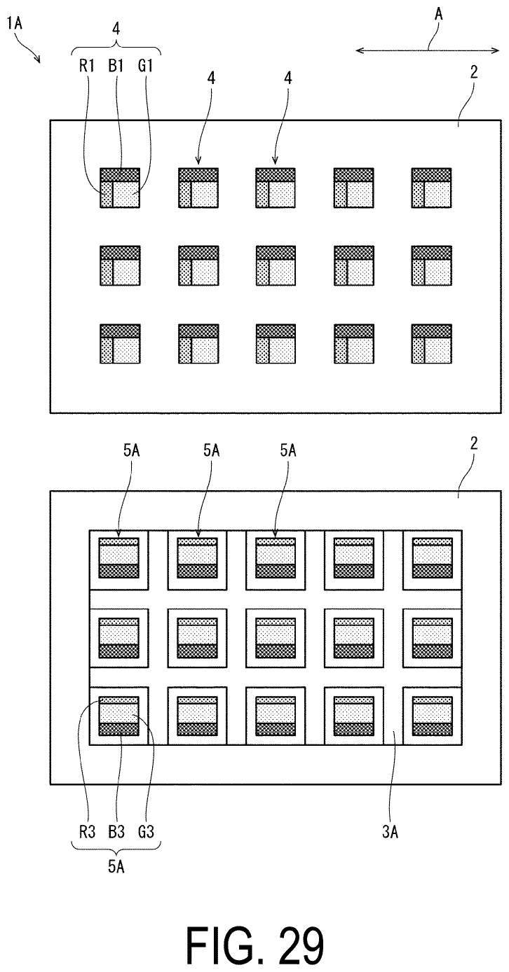

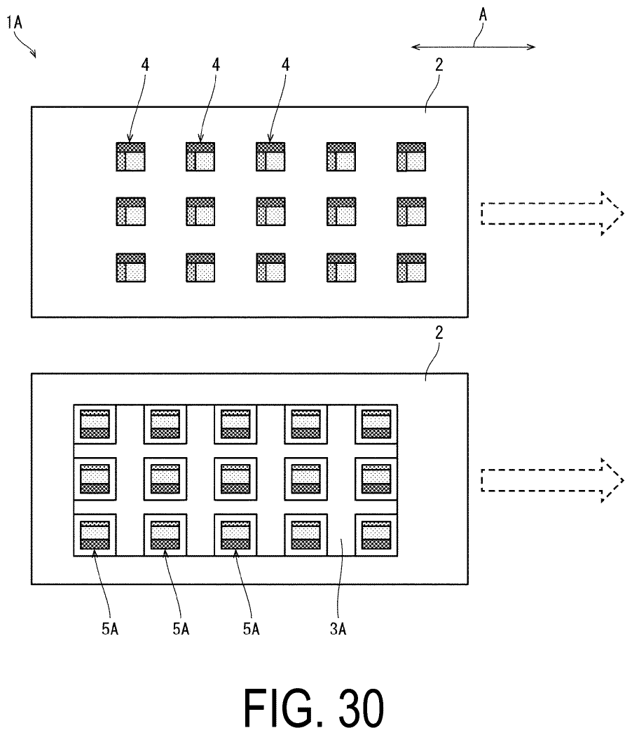

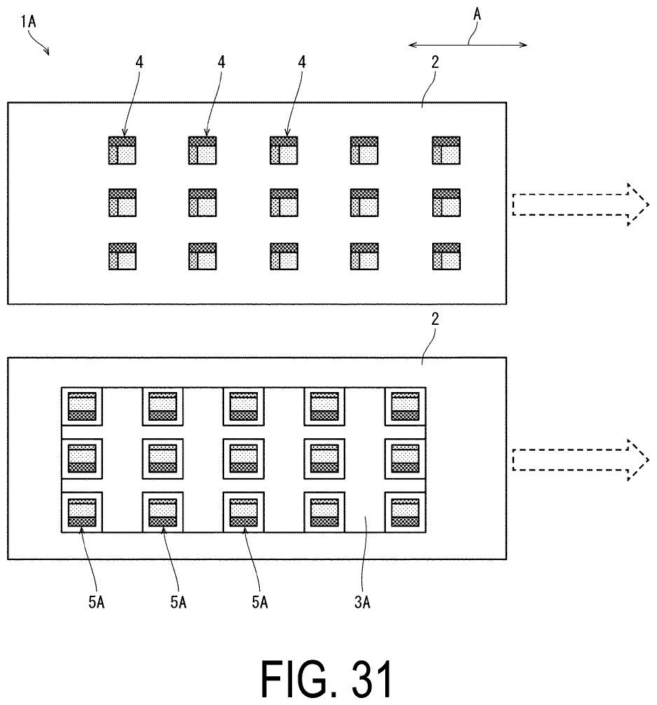

FIG. 29 is a plan view illustrating an example of stretching of the stretchable display device 1A. FIG. 30 is a plan view illustrating an operation of the stretchable display device 1A. FIG. 31 is a plan view illustrating the operation when the stretchable display device 1A is further stretched. Constituent elements similar to/same as the constituent elements described above are given the same reference numerals. Thus, detailed descriptions of the constituent elements are not repeated.

The pixel 4 of the upper substrate 2 includes the subpixel R1, the subpixel G1, and the subpixel B. The pixel 5A of the lower substrate 3A includes the subpixel R3, the subpixel G3, and the subpixel B3. The subpixel R1 and the subpixel R3 emit light of the same color and have different light-emitting areas from each other. The subpixel G1 and the subpixel G3 emit light of the same color and have different light-emitting areas from each other. The subpixel B1 and the subpixel B3 emit light of the same color and have different light-emitting areas from each other. As described above, between the pixels 4 and 5A, the light-emitting areas of the subpixels R1 and R3 that emit light of the same color are different from each other, the light-emitting areas of the subpixels G1 and R3 that emit light of the same color are different from each other, and the light-emitting areas of the subpixels B1 and B3 that emit light of the same color are different from each other.

In a state illustrated in FIG. 29 in which the upper substrate 2 of the stretchable display device 1A is not stretched, the pixels 4 of the upper substrate 2 and the pixels 5A of the lower substrate 3A overlap each other in a plan view.

As illustrated in FIG. 30, when the upper substrate 2 is stretched along the direction of the arrow A, the lower substrate 3A is also stretched along the direction of the arrow A. Therefore, the gaps between the pixels 4 adjacent to each other along the direction of the arrow A are widened, and the gaps between the pixels 5A adjacent to each other along the direction of the arrow A are widened.

Next, as illustrated in FIG. 31, when the upper substrate 2 is further stretched along the direction of the arrow A, the lower substrate 3A is also further stretched along the direction of the arrow A. Therefore, the gaps between the pixels 4 adjacent to each other along the direction of the arrow A are further widened, and the gaps between the pixels 5A adjacent to each other along the direction of the arrow A are further widened. As a result, the gaps between the pixels 4 adjacent to each other along the direction of the arrow A overlap the pixels 5 in a plan view.

### Third Embodiment

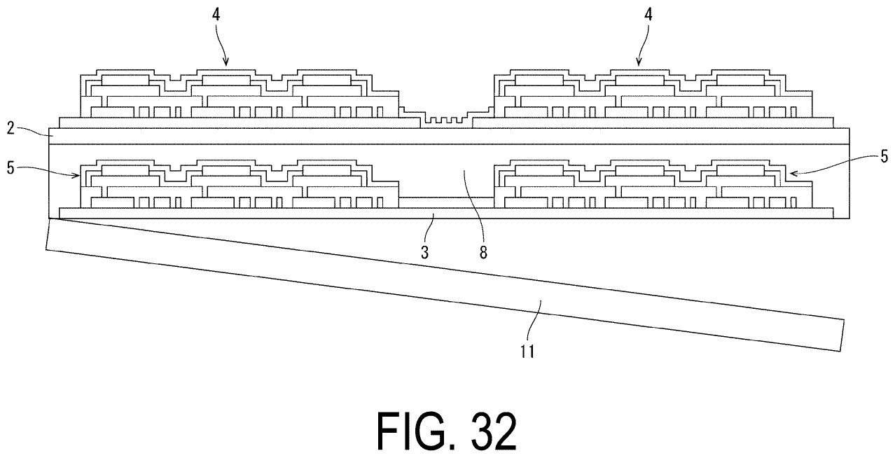

FIG. 32 is a cross-sectional view illustrating a manufacturing method of the stretchable display device 1 according to a third embodiment. Constituent elements similar to/same as the constituent elements described above are given the same reference numerals. Thus, detailed descriptions of the constituent elements are not repeated.

Hereinafter, the manufacturing method of the stretchable display device 1 will be described.

### Manufacture of Lower Display Region

First, a lower display region is manufactured. Specifically, a resin substrate is formed on a support substrate 11, such as a transparent mother glass. Then, a base coat layer is formed on the resin substrate. Next, a thin film transistor layer (TFT layer) is formed on the base coat layer. Thereafter, a light-emitting element layer, such as a top emission type OLED element layer, is formed on the thin film transistor layer. Then, a sealing layer is formed to cover the light-emitting element layer. Next, the support substrate 11 is peeled from the resin substrate by reducing a bonding force between the support substrate 11 and the resin substrate by irradiating laser light through the support substrate 11 onto a lower face of the resin substrate. Thereafter, a lower face film is bonded to the lower face of the resin substrate.

The resin substrate corresponds to the lower substrate 3. The light-emitting element layer corresponds to the pixel 5.

### Manufacture of Upper Display Region

Then, an upper display region is manufactured. Specifically, a resin substrate is formed on a support substrate such as a transparent mother glass. Then, a base coat layer is formed on the resin substrate. Next, a thin film transistor layer (TFT layer) is formed on the base coat layer. Thereafter, a light-emitting element layer, such as a top emission type OLED element layer, is formed on the thin film transistor layer. Then, a sealing layer is formed to cover the light-emitting element layer. The light-emitting element layer corresponds to the pixel 5.

Next, the TFT layer and the OLED element layer are separated into pixel units. Then, the resin substrate is etched to form the upper display region for each of the pixel units. Then, a support substrate, such as a glass substrate or a resin substrate having a relatively high Young's modulus, is bonded to an upper surface element side of the upper display region. Next, the support substrate is peeled from the resin substrate by reducing a bonding force between the support substrate and the resin substrate by irradiating laser light through the support substrate onto the lower face of the resin substrate. Thereafter, the stretchable upper substrate 2 made of an elastic polymer such as silicone rubber or polyurethane is bonded to the resin substrate side of the upper display region. After the upper substrate 2 is bonded, the support substrate is removed.

Conductive wiring lines are formed on the upper substrate 2 in advance. The conductive wiring line can be formed, for example, by weaving conductive fibers into the tipper substrate 2, by coating a metal conductor on the upper substrate 2 and then patterning it, or by printing and forming a conductive paste on the upper substrate 2 by dispersing and mixing, in advance, a conductive substance such as silver, gold, or carbon in an elastic polymer such as silicone rubber or polyurethane.

As long as the conductive wiring line does not break in resistance to the stretching of the upper substrate 2, a pattern shape of the conductive wiring line can be formed in an arbitrary shape such as a linear structure, a curved structure, a 3D concave-convex structure, a zigzag structure, a ripple structure, a wave structure, or a spiral structure, and is not limited to these examples. Further, the conductive wiring line is formed on the upper substrate 2, and the periphery thereof is subjected to punching processing using laser light, etching, or the like in accordance with the shape of the conductive wiring, thus further improving the stretchability.

When the upper substrate 2 has an area larger than that of the lower substrate 3 and is formed so as to cover the lower substrate 3, a degree of freedom of movement of the pixels 4 at the time of stretching is further improved.

The Young's modulus of the upper substrate 2 is determined as desired depending on a degree of stretching, but, in order to obtain sufficient stretching, is preferably equal to or less than 10 MPa, and is more preferably in a range of 0.1 to 10 MPa.

### Bonding of Lower Display Region and Upper Display Region

Then, the lower display region and the upper display region are bonded to each other. Specifically, a space larger than at least the height of the pixel 5 is provided between the tipper substrate 2 and the lower substrate 3, and the upper substrate 2 including the upper display region, a bonding substrate, and the like is bonded to the resin substrate (lower substrate 3) including the lower display region.

For bonding, for example, a gel-like resin such as an elastic polymer, such as silicone rubber or polyurethane, is used. These materials can be the same as or different from that of the upper substrate 2, but the Young's modulus thereof is preferably substantially the equal to or less than that of the upper substrate 2, from the viewpoint of reducing a stretching stress applied to the lower display region. Further, it is desirable that the Young's modulus of these materials is equal to or less than one half of that of the resin substrate of the lower substrate 3. The Young's modulus can be adjusted as desired by adding a filler such as silica powder, carbon black, alumina powder, or the like, but care must be taken so as not to significantly reduce the transparency. The Young's modulus can also be adjusted by a blending ratio of a crosslinking agent or curing agent of the gel resin.

From the viewpoint of reducing the stretching stress on the lower substrate 3 and facilitating the stretching of the upper substrate 2, as described above, the thixotropic material 8 such as modified silicone having thixotropic properties, may be used as a bonding portion between the lower substrate 3 and the upper substrate 2. Further, two or more types of layer structure, in which the Young's modulus decreases from near to the lower substrate 3 to near to the upper substrate 2, may be formed in a stepwise manner, or a single layer structure in which the Young's modulus gradually decreases may be formed.

A part of the lower substrate 3 may be caused to be stretchable. The material and the Young's modulus thereof at this time may be the same as or different from those of the upper substrate 2.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

### REFERENCE SIGNS LIST

1 Stretchable display device
2 Upper substrate
3 Lower substrate
4 Pixel (first pixel, second pixel)
5 Pixel (third pixel)
6 Upper holding region
7 Upper stretching region
8 Thixotropic agent
9 Lower holding region
10 Lower stretching region
12 Housing
13 Light guide layer

1. A stretchable display device comprising:
an upper substrate stretchable in a first direction parallel to a surface;
a lower substrate positioned below the upper substrate and being less stretchable in the first direction than the upper substrate;
a first pixel and a second pixel provided on the upper substrate, and being adjacent to each other; and
a third pixel provided on the lower substrate.

2. The stretchable display device according to claim 1,
wherein, in a first state in which the upper substrate is not stretched, the first pixel and the third pixel overlap each other in a plan view.

3. The stretchable display device according to claim 1,
wherein, in a second state in which the upper substrate is stretched, a gap between the first pixel and the second pixel overlaps the third pixel in a plan view.

4. The stretchable display device according to claim 1,
wherein lighting control of the third pixel is performed in accordance with a size of a gap between the first pixel and the second pixel.

5. The stretchable display device according to claim 1,
wherein the upper substrate covers a side surface of the lower substrate.

6. The stretchable display device according to claim 5, further comprising:
a housing configured to hold the upper substrate.

7. The stretchable display device according to claim 6,
wherein both of ends of the upper substrate are fixed to the housing, and
the side surface of the lower substrate is fixed to both the ends of the upper substrate.

8. The stretchable display device according to claim 1,
wherein a thixotropic material is filled between the lower substrate and the upper substrate, and
the thixotropic material covers the third pixel.

9. The stretchable display device according to claim 3,
wherein, in the second state, the upper substrate is allowed to have an upwardly convex shape.

10. The stretchable display device according to claim 1,
wherein stretchability of the lower substrate in the first direction is uniform as a whole.

11-15. (canceled)

16. The stretchable display device according to claim 1,
wherein a void is formed around the third pixel.

17. The stretchable display device according to claim 1,
wherein the first pixel, the second pixel, and the third pixel each include a plurality of subpixels emitting light of a different color.

18. The stretchable display device according to claim 17,
wherein the first pixel includes a first subpixel, a second subpixel, and a third subpixel
the second pixel includes a fourth subpixel, a fifth subpixel, and a sixth subpixel
a light-emitting area ratio between a light-emitting area of the first subpixel, a light-emitting area of the second subpixel, and a light-emitting area of the third subpixel is equal to a light-emitting area ratio between a light-emitting area of the fourth subpixel, a light-emitting area of the fifth subpixel, and a light-emitting area of the sixth subpixel.

19. The stretchable display device according to claim 17,
wherein, in the first pixel and the third pixel, light-emitting areas of the subpixels emitting light of the same color are different from each other.

20. The stretchable display device according to claim 6,
wherein the thixotropic material is in a liquid state or a semi-solid state.

21. The stretchable display device according to claim 1, further comprising:
a light guide layer overlapping the third pixel in a plan view.

22. The stretchable display device according to claim 1,
wherein the upper substrate includes an elastic polymer.

23. The stretchable display device according to claim 1,
wherein the Young's modulus of the upper substrate is equal to or less than 10 MPa.

24. The stretchable display device according to claim 6,
wherein the Young's modulus of the thixotropic material is equal to or less than the Young's modulus of the upper substrate.

25. The stretchable display device according to claim 6,
wherein the Young's modulus of the thixotropic material is equal to or less than one half of the Young's modulus of the lower substrate.
